(19) United States
(12) Patent Application Publication
(10) Pub. No.: US 2003/0139034 A1
(43) Pub. Date: Jul. 24, 2003

(54) Dual damascene structure and method of making same

(76) Inventor: Yu-Shen Yuang, Miao-Li Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,364

(22) Filed: Jul. 7, 2002

Related U.S. Application Data
(62) Division of application No. 09/683,579, filed on Jan. 22, 2002, now abandoned.

(51) Int. Cl. H01L 21/4763; H01L 21/44

(52) U.S. Cl. 438/634; 438/633; 438/687

(57) ABSTRACT

A dielectric barrier sidewall protected via in combination with a conventional metal barrier is integrated in a dual damascene process. Via reliability, copper filling ability and copper CMP uniformity will be significantly improved according to this invention.

### CROSS REFERENCE TO RELATED APPLICATIONS

This application is a division of application Ser. No. 09/683,579 filed on Jan. 22, 2002.

### BACKGROUND OF INVENTION

1. Field of the Invention

This invention relates to the field of integrated circuits fabrication, in particular, to a dual damascene structure and its fabrication method.

2. Description of the Prior Art

The copper-damascene approach has been adopted in various integrated circuit fabrications since it efficiently provides high yield and large process windows required for volume manufacturing. For example, damascene wiring lines can be used to form bit lines in DRAM devices, with processing similar to the formation of W studs in the logic and DRAM devices. Generally, damascene copper wiring interconnects are formed by depositing a dielectric layer on a planar surface, patterning it using photolithography and oxide RIE, metallizing with tantalum (which is used as a barrier), forming a copper seed layer by physical vapor deposition (PVD) and then electrochemically depositing (ECD) copper by plating. The excess copper is removed by chemical mechanical polishing (CMP), while the troughs or channels remain filled with copper.

FIG. 1 is a schematic, cross-sectional diagram showing a prior art dual damascene structure 11. As shown in FIG. 1, the dual damascene structure 11 formed within a dielectric layer 20 is composed of a via opening 22 and a trench 23. A conductive layer or an underlying metal wire 14 is formed in a dielectric layer 12 beneath the via hole 22. A Cu conductive layer or a upper metal wire 24 fills the trench 23 and is electrically connected with the underlying metal wire 14 via a via plug 22a. A barrier layer 25 is formed to isolate the metal and avoid diffusion of copper atoms, which usually cause a leakage current. Suitable materials used to form the barrier layer 25 include Ti, TiN, TaN, WN, etc.

Nevertheless, some issues emerge while the critical dimension shrinks. First, PVD-TaN provides poor conformal coverage inside features with aspect ratios greater than 2:1 (height diameter ratio) thereby resulting in lack of copper fill-in in windows, vias or damascene structures and produces voids.

Via open failure is another problem which occurs when manufacturing the copper dual damascene interconnection. Via open failure occurs when a via barrier breaks or a bottom via opens due to stress. The broken barrier enables Cu diffusion causing a leakage current, while the bottom via open causes an open circuit between the underlying wire 14 and the upper wire 24. The via open failure problem is worse when the dielectric layer 20 is composed of a dielectric material with a large coefficient of TM thermal expansion (CTE), such as a SiLK™, polymer-type organics, or porous materials.

### SUMMARY OF INVENTION

The claimed invention is a method for making a dual damascene structure having improved via reliability and an extended copper filling process window.

The dual damascene structure according to the claimed invention includes a base layer having a conductive layer formed thereon; a first dielectric layer on the base layer; an etch stop layer on the first dielectric layer; a via opening in the first dielectric layer and the etch stop layer to expose a portion of the conductive layer; a second dielectric layer on the etch stop layer; a trench line in the second dielectric layer overlying the via opening; a dielectric barrier covering sidewalls of the via opening; and a metal barrier covering interior surface of the trench line, the dielectric barrier and bottom of the via opening.

The method of making the above dual damascene structure includes the following steps. A substrate with a conductive layer formed is provided. A first dielectric layer is formed over the substrate and the conductive layer. An etch stop layer is deposited on the first dielectric layer. A via opening is formed in the etch stop layer and the first dielectric layer to expose a portion of the conductive layer. A second dielectric layer is deposited over the etch stop layer, sidewalls and bottom of the via opening. A third dielectric layer is formed over the second dielectric layer and the third dielectric layer filling the via opening. A hard mask is formed on the third dielectric layer. A resist layer is formed over the hard mask, the resist layer comprising a line pattern exposing an area of the hard mask overlying the via opening. The hard mask, the third dielectric layer, the second dielectric layer are etched away through the line pattern leaving a portion of the second dielectric layer on sidewalls of the via opening so as to form a via opening protected by a dielectric barrier and a trench line overlying the via opening. A metal barrier is formed on the dielectric barrier, bottom of the via opening and interior surface of the trench line.

The most important feature of the claimed invention is that the dielectric barrier covering sidewalls of the via opening increases resistance to via stress and avoids via opening or broken barriers. Furthermore, the use of the dielectric barrier in combination with a conventional metal barrier improves uniformity when the copper is removed by chemical-mechanical polishing.

It is to be understood that both the forgoing general description and the following detailed description are exemplary, and are intended to provide further explanation of the invention as claimed. Other advantages and features of the invention will be apparent from the following description, drawings and claims.

### BRIEF DESCRIPTION OF DRAWINGS

The invention can be fully understood by reading the following detailed description of the preferred embodiments, with reference made to the accompanying drawings as follows:

FIG. 1 is a schematic, cross-sectional diagram showing a prior art dual damascene structure;

FIG. 2 to FIG. 5 are enlarged cross-sectional views illustrating fabrication process of a dual damascene structure according to the first preferred embodiment of the present invention; and

FIG. 6 to FIG. 9 are schematic, cross-sectional diagrams showing a second preferred embodiment according to the present invention.

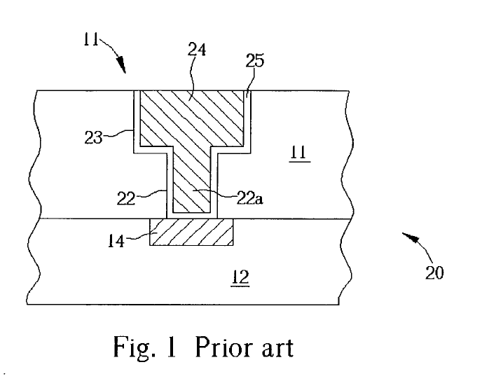

### DETAILED DESCRIPTION

The present invention features a novel dual damascene structure with dielectric barrier protected via walls. After the formation of the dielectric barrier on sidewalls of the via, a conventional metal barrier is then deposited on the dielectric barrier.

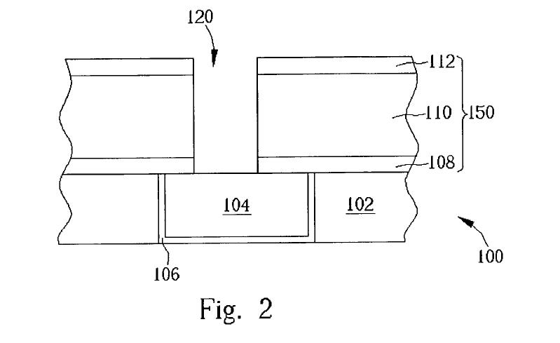

FIG. 2 to FIG. 5 are enlarged cross-sectional views illustrating fabrication process of a dual damascene structure according to the first preferred embodiment of the present invention. As shown in FIG. 2, a substrate 100 containing a base layer 102 and a metal line 104 is provided. Structures under the base layer 102 are omitted for simplicity. The metal line 104 is formed in the base layer 102 by damascene process and is isolated by a barrier layer 106 from the adjacent base layer 102. A stacked layer 150 consisting of a cap layer 108, a dielectric layer 110 and an etch stop layer 112 is formed over the base layer 102 and the metal line 104. Preferably, the cap layer 108 is a silicon nitride layer formed by, for example, chemical vapor deposition (CVD). The dielectric layer 110 may be formed of inorganic or organic dielectric materials with a low dielectric constant (k) of less than 3.2. Some exemplary low k dielectric materials include SiLK™, Flare™, HSQ, PAE-II and Parylene. A via opening 120 is then formed in the stacked layer 150. The via opening 120 is formed by the following steps. A first patterned photoresist layer (not shown) is formed to expose a desired via region above the metal line 104. The stacked layer 150 is etched using the first patterned photoresist layer as an etching mask to expose a portion of the underlying metal line 104. The first photoresist layer is then stripped by a method known in the art.

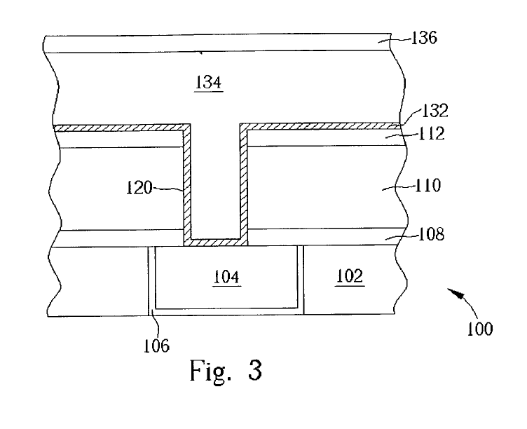

Referring to FIG. 3, a conformal dielectric barrier layer 132 is deposited onto the etch stop layer 112 and interior surface, i.e. sidewalls and bottom, of the via opening 120 by, for example, plasma enhanced CVD (PECVD). Preferably, the dielectric barrier layer 132 is composed of silicon nitride. The thickness of the dielectric barrier layer 132 is preferably between 50 and 300 angstroms depending on diameter of the via opening 120. For example, a via opening 120 with a diameter of approximately 0.2 microns has a dielectric layer thickness of between 80-120 angstroms, preferably 100 angstroms. A dielectric layer 134 of low k dielectric materials such as spin on organic polymers is then formed on the dielectric barrier layer 132 and the dielectric layer 134 fills the via opening 120. A hard mask 136 is thereafter formed on the dielectric layer 134. In the first preferred embodiment the hard mask 136 is composed of silicon nitride.

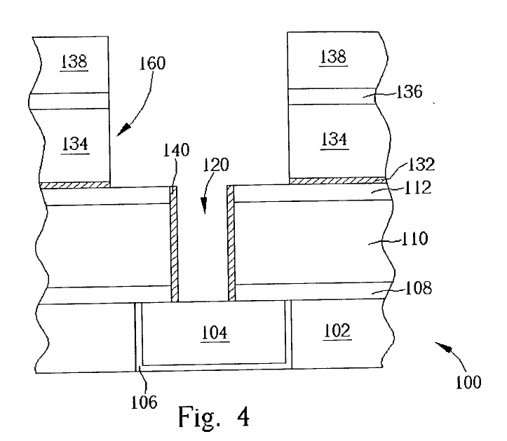

Referring to FIG. 4, a second patterned photoresist layer 138 is formed to expose a desired trench region above the hard mask 136. Using the second photoresist layer 138 as a mask, the hard mask 136, dielectric layer 134 and dielectric barrier layer 132 within the exposed trench region are successively etched away to form a trench 160. The trench 160 is generally used to accommodate a copper wiring line in the follow-up process. The underlying metal line 104 is exposed through the via opening 120 by etching away the dielectric barrier layer 132 at the bottom of the via opening 120. At this stage, dielectric barrier spacers 140 are formed on sidewalls of the via opening 120. After the formation of the barrier spacers 140, the second photoresist layer 138 is stripped away.

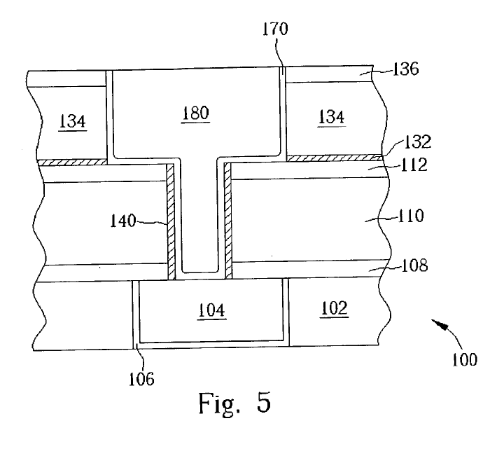

Referring to FIG. 4 and FIG. 5, a metal barrier 170 is formed by, for example, physical vapor deposition (PVD), over the hard mask 136, the dielectric barrier spacers 140 and the interior surfaces of the trench 160 and via opening 120. The metal barrier 170 may comprise of either Ta, TaN, TiN or Ta/TaN alloy. The formation of the tantalum layer is by conventional methods and may be done by PVD or chemical vapor deposition (CVD) for example. The tantalum layer is generally 1 to 20 nm thick. The tantalum nitride layer may be formed by plasma nitriding, PVD, CVD or the like. The thickness of the TaN layer in a Ta/TaN alloy barrier is from approximately 1 to 100 nm. Copper 180 is then formed to fill the trench 160 and via opening 120. Copper 180 formation is generally done by applying a PVD, CVD or an electroless seed layer (not shown) followed by ECD in the form of electroless or electrolytic plating. The copper may be planarized by chemical-mechanical polishing (CMP), as shown in FIG. 5.

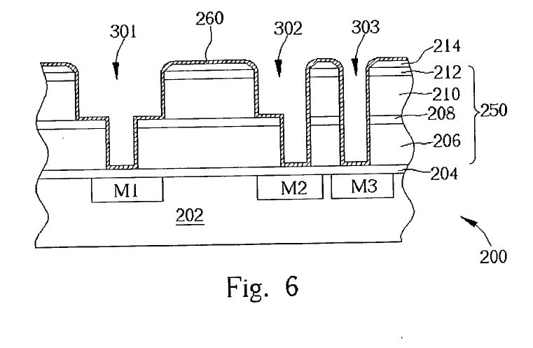

FIG. 6 to FIG. 9 are schematic, cross-sectional diagrams showing a second preferred embodiment according to the present invention. As shown in FIG. 6, a substrate 200 comprises damascene trough 301, damascene trough 302 and damascene trough 303 formed in the dielectric stack 250 consisting of a first dielectric layer 206, an etch stop layer 208, a second dielectric layer 210, a first hard mask 212 and a second hard mask 214. Each damascene trough structure includes a trench and a via opening exposing a portion of a cap layer 204 above a conductive layer (i.e. M1, M2, M3 shown in FIG. 6) such as a copper wiring line of a base layer 202. In the second preferred embodiment, the damascene trough 301, damascene trough 302 and damascene trough 303 are formed simultaneously by using a self-aligned dual damascene process known by those versed in the art. The detailed steps are omitted in the following discussion.

Still referring to FIG. 6, after the formation of the damascene troughs 301, 302, and 303, the second hard mask 214 is often worn to an extent that could affect the following copper CMP uniformity (poor hard mask control). To help to alleviate the CMP uniformity variation problem, a conformal dielectric barrier 260 is deposited on the dielectric stack 250 and interior surfaces of the damascene troughs 301, 302, and 303. Preferably, the dielectric barrier 260 has a high etch selectivity with respect to the second hard mask 214. In the second preferred embodiment, the first hard mask 212 is composed of silicon nitride, the second hard mask 214 is composed of silicon oxide, while the dielectric barrier 260 is composed of silicon nitride. The dielectric barrier 260 is preferably formed by PECVD.

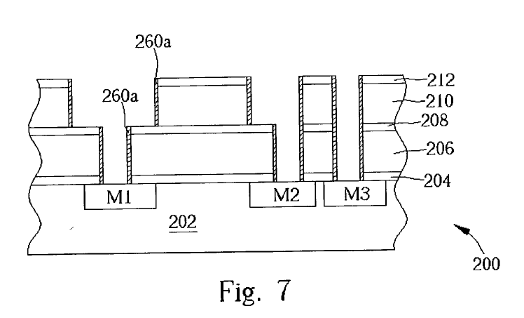

Referring to FIG. 7, the dielectric barrier 260 is anisotropically etched back to form barrier spacers 260a on sidewalls of the damascene troughs 301, 302, and 303. The underlying metal lines are partially exposed by etching the cap layer 204. The second hard mask 214 is removed during the etching of the cap layer 204. An alternative method to remove the second hard mask 214 includes the following steps. The dielectric barrier 260 is etched back to expose the cap layer 204 and the second hard mask 214. The second hard mask 214 is then washed away by, for example, diluted HF or the like.

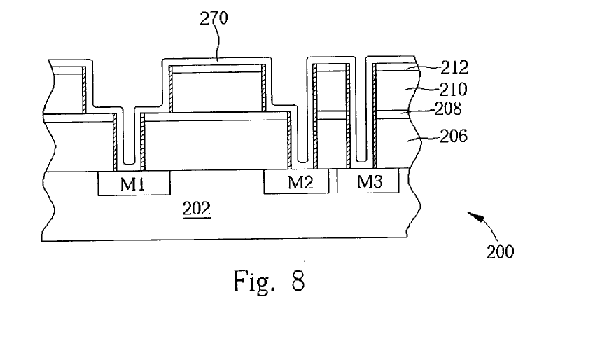

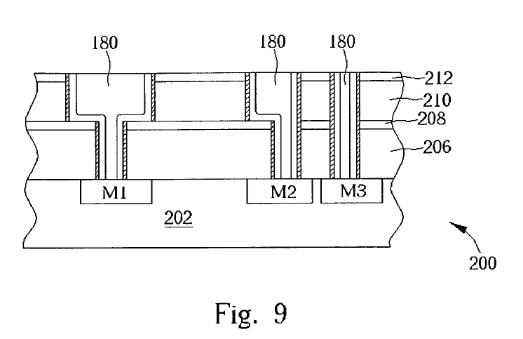

Referring to FIG. 8, after the formation of the barrier spacers 260a, a metal barrier 270 is formed by PVD. For example, over the first hard mask 212, the dielectric barrier spacers 206a and the interior surfaces of the damascene troughs 301, 302, and 303. The metal barrier 270 may comprise of Ta, TaN, TiN or Ta/TaN alloy. The formation of the tantalum layer is conventional and may be done by either PVD or CVD. The tantalum nitride layer may be formed by plasma nitriding, PVD, CVD or the like. The thickness of the TaN layer in a Ta/TaN alloy barrier is between 1 to 100 nm. Copper 280 is then formed to fill the damascene troughs 301, 302, and 303. The formation of copper 180 is generally done by applying either a PVD or CVD or electroless seed layer (not shown) followed by ECD in the form of electroless or electrolytic plating. Finally, as shown in FIG. 9, excess copper 280 outside the damascene troughs 301, 302, and 303 is planarized by CMP.

In brief, the present invention include the following advantages: improved resistance to via stress caused by metals or inter-metal dielectric (IMD) layers having a high coefficient of thermal expansion, a much thinner metal barrier which allows an extended process window, and better CMP uniformity.

Those skilled in the art will readily observe that numerous modification and alterations of the device may be made while retaining the teachings of the invention. Accordingly, the above disclosure should be construed as limited only by the metes and bounds of the appended claims.

What is claimed is:

1. A method of fabricating a copper dual damascene interconnect capable of improving via reliability, comprising the steps of:
providing a substrate having a conductive layer formed thereon;
forming a first dielectric layer over the substrate and the conductive layer;
depositing an etch stop layer on the first dielectric layer;
forming a via opening in the etch stop layer and the first dielectric layer to expose a portion of the conductive layer;
depositing a second dielectric layer over the etch stop layer, sidewalls and bottom of the via opening;
forming a third dielectric layer over the second dielectric layer and the third dielectric layer filling the via opening;
forming a hard mask on the third dielectric layer;
forming a resist layer over the hard mask, the resist layer comprising a line pattern exposing an area of the hard mask overlying the via opening;
etching away the hard mask, the third dielectric layer, the second dielectric layer through the line pattern leaving a portion of the second dielectric layer on sidewalls of the via opening so as to form a via opening protected by a dielectric barrier and a trench overlying the via opening; and
forming a metal barrier on the dielectric barrier, bottom of the via opening and interior surface of the trench.

2. The method according to claim 1 wherein the first and second have a dielectric constant less than 3.2.

3. The method according to claim 1 wherein the dielectric barrier has a thickness of less than 300 angstroms.

4. The method according to claim 1 wherein the second dielectric layer is composed of silicon nitride.

5. The method according to claim 1 wherein the metal barrier is composed of Ta/TaN.

6. A method of fabricating a dual damascene structure capable of improving via reliability, comprising the steps of:
providing a substrate;
forming a conductive layer over the substrate;
forming a cap layer over the conductive layer;
forming a dual damascene opening in a stacked dielectric layer over the substrate to expose a portion of the cap layer above the conductive layer, wherein the dual damascene opening includes a via opening and a trench;
depositing a non-metal barrier layer on the stacked dielectric layer and interior surface of the dual damascene opening;
etching back the non-metal barrier layer to form non-metal barrier spacers on sidewalls of the trench and the via opening and etching away the cap layer to expose the conductive layer through the via opening; and
forming a metal barrier on the non-metal barrier spacers and interior surface of the dual damascene opening not covered by the non-metal barrier spacers.

7. The method according to claim 6 wherein the stacked dielectric layer comprises a first dielectric layer, an etch stop layer on the first dielectric layer, a second dielectric layer atop the etch stop layer, a first hard mask over the second dielectric layer, and a second hard mask over the first hard mask.

8. The method according to claim 7 wherein the first hard mask is composed of silicon nitride and the second hard mask is composed of silicon oxide.

9. The method according to claim 7 wherein the second hard mask is removed during the etch of the cap layer.

10. The method according to claim 6 wherein the non-metal barrier spacer has a thickness of less than 300 angstroms.

11. The method according to claim 10 wherein the non-metal barrier spacer is composed of silicon nitride.

12. The method according to claim 10 wherein the non-metal barrier spacer is formed by plasma enhanced chemical vapor deposition (PECVD).

13. The method according to claim 6 wherein the metal barrier is composed of Ta/TaN.
